(19) United States
(12) Patent Application Publication
(10) Pub. No.: US 2022/0406710 A1
(43) Pub. Date: Dec. 22, 2022

(54) SEMICONDUCTOR DEVICE AND MANUFACTURING METHOD THEREOF

(71) Applicant: Kioxia Corporation, Tokyo (JP)

(72) Inventors: Tatsuya NOMURA, Mie (JP); Daichi NISHIKAWA, Mie (JP); Daisuke IKENO, Yokkaichi (JP); Akihiro KAJITA, Yokkaichi (JP)

(73) Assignee: Kioxia Corporation, Tokyo (JP)

(21) Appl. No.: 17/682,810

(22) Filed: Feb. 28, 2022

(30) Foreign Application Priority Data
Jun. 21, 2021 (JP) 2021-102638

(51) Int. Cl. H01L 23/522; H01L 23/532; H01L 21/3213

(52) U.S. Cl. CPC H01L 23/5228; H01L 23/5226; H01L 23/53266; H01L 21/3213

(57) ABSTRACT

A semiconductor device includes a conductive layer extending in a first direction, including a first surface, a second surface facing the first surface in a second direction intersecting the first direction, a third surface, and a fourth surface facing the third surface in a third direction intersecting the first direction and the second direction, and containing a first element which is at least one element of tungsten (W) or molybdenum (Mo); a first region disposed on a first surface side of the conductive layer, containing a second element which is at least one element of tungsten (W) or molybdenum (Mo), and a third element which is at least one element of sulfur (S), selenium (Se), or tellurium (Te), and including a first crystal; and a second region disposed on a second surface side of the conductive layer, containing the second element and the third element, and including a second crystal.

### CROSS-REFERENCE TO RELATED APPLICATION

This application is based upon and claims the benefit of priority from Japanese Patent Application No. 2021-102638, filed Jun. 21, 2021, the entire contents of which are incorporated herein by reference.

### FIELD

Embodiments described herein relate generally to a semiconductor device and a manufacturing method thereof.

### BACKGROUND

In association with miniaturization of a semiconductor device, miniaturization of a wiring electrically connecting elements in the semiconductor device is also required. It is desired to achieve a wiring having a low electrical resistance even if a wiring width is reduced.

### DESCRIPTION OF THE DRAWINGS

FIG. 1 is a schematic cross-sectional view of a wiring layer of a semiconductor device according to a first embodiment.

FIG. 2 is a schematic plan view of the wiring layer of the semiconductor device according to the first embodiment.

FIG. 3 is a schematic cross-sectional view of the wiring layer of the semiconductor device according to the first embodiment.

FIG. 4 is a schematic cross-sectional view illustrating a method for manufacturing the semiconductor device according to the first embodiment.

FIG. 5 is a schematic cross-sectional view illustrating the method for manufacturing the semiconductor device according to the first embodiment.

FIG. 6 is a schematic cross-sectional view illustrating the method for manufacturing the semiconductor device according to the first embodiment.

FIG. 7 is a schematic cross-sectional view illustrating the method for manufacturing the semiconductor device according to the first embodiment.

FIG. 8 is a schematic cross-sectional view illustrating the method for manufacturing the semiconductor device according to the first embodiment.

FIG. 9 is a schematic cross-sectional view of a wiring layer of a modification of the semiconductor device according to the first embodiment.

FIG. 10 is a schematic cross-sectional view of a wiring layer of a semiconductor device according to a second embodiment.

FIG. 11 is a schematic cross-sectional view of the wiring layer of the semiconductor device according to the second embodiment.

FIG. 12 is a schematic cross-sectional view of the wiring layer of the semiconductor device according to the second embodiment.

FIG. 13 is a schematic cross-sectional view of the wiring layer of the semiconductor device according to the second embodiment.

FIG. 14 is a schematic cross-sectional view illustrating a method for manufacturing the semiconductor device according to the second embodiment.

FIG. 15 is a schematic cross-sectional view illustrating the method for manufacturing the semiconductor device according to the second embodiment.

FIG. 16 is a schematic cross-sectional view illustrating the method for manufacturing the semiconductor device according to the second embodiment.

FIG. 17 is a schematic cross-sectional view illustrating the method for manufacturing the semiconductor device according to the second embodiment.

FIG. 18 is a schematic cross-sectional view illustrating the method for manufacturing the semiconductor device according to the second embodiment.

FIG. 19 is a schematic cross-sectional view illustrating the method for manufacturing the semiconductor device according to the second embodiment.

FIG. 20 is a schematic cross-sectional view illustrating the method for manufacturing the semiconductor device according to the second embodiment.

FIG. 21 is a schematic cross-sectional view of a wiring layer of a modification of the semiconductor device according to the second embodiment.

FIG. 22 is a circuit diagram of a semiconductor device according to a third embodiment.

### DETAILED DESCRIPTION

At least one embodiment provides a semiconductor device provided with a wiring having a low electrical resistance.

In general, according to at least one embodiment, a semiconductor device includes a first conductive layer extending in a first direction, the first conductive layer including a first surface, a second surface facing the first surface in a second direction intersecting the first direction, a third surface, and a fourth surface facing the third surface in a third direction, the third direction intersecting the first direction and the second direction, the first conductive layer containing a first element which is at least one element selected from a group consisting of tungsten (W) or molybdenum (Mo); a first region disposed on a first surface side of the first conductive layer, the first region containing a second element and a third element, is the second element being at least one element selected from the group consisting of tungsten (W) or molybdenum (Mo), the third element being at least one element selected from a group consisting of sulfur (S), selenium (Se), or tellurium (Te), and including a first crystal; and a second region disposed on a second surface side of the first conductive layer, the second region containing the second element and the third element, and including a second crystal.

Hereinafter, embodiments will be described with reference to the drawings. In the following description, the same or similar members are denoted by the same reference numerals, and the description of the members once described is appropriately omitted.

In addition, in the present specification, a term “upper” or “lower” may be used for convenience. The term “upper” or “lower” indicates, for example, a relative positional relation in the drawings. The term “upper” or “lower” does not necessarily define a positional relation with respect to gravity.

Qualitative and quantitative analyses of chemical compositions of members forming a semiconductor device in the present specification may be performed by, for example, secondary ion mass spectrometry (SIMS), and energy dispersive X-ray spectroscopy (EDX). For example, a transmission electron microscope (TEM) may be used for measuring thicknesses of each member forming the semiconductor device, a distance between the members, or the like. An electron beam diffraction analysis (EBD) or a synchrotron radiation X-ray absorption fine structure (XAFS) can be used for identifying crystal systems of the members forming the semiconductor device. In addition, the crystal systems of the members forming the semiconductor device can also be identified, for example, by analyzing an electron diffraction image obtained by the transmission electron microscope by using a fast Fourier transform method.

### First Embodiment

A semiconductor device according to a first embodiment includes a first conductive layer extending in a first direction, the first conductive layer including a first surface, a second surface facing the first surface in a second direction intersecting the first direction, a third surface, and a fourth surface facing the third surface in a third direction, the third direction intersecting the first direction and the second direction, the first conductive layer containing a first element which is at least one element selected from a group consisting of tungsten (W) or molybdenum (Mo); a first region disposed on a first surface side of the first conductive layer, the first region containing a second element and a third element, is the second element being at least one element selected from the group consisting of tungsten (W) or molybdenum (Mo), the third element being at least one element selected from a group consisting of sulfur (S), selenium (Se), or tellurium (Te), and including a first crystal; and a second region disposed on a second surface side of the first conductive layer, the second region containing the second element and the third element, and including a second crystal.

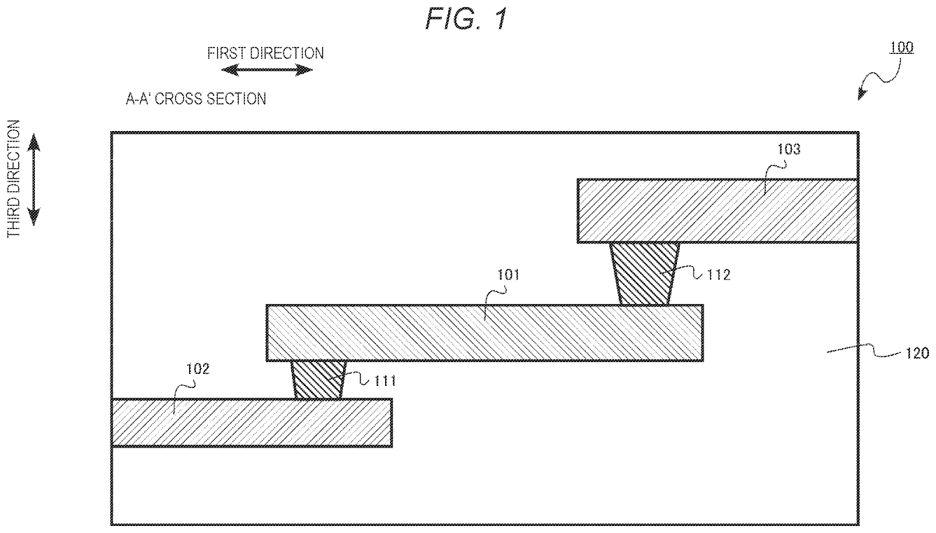

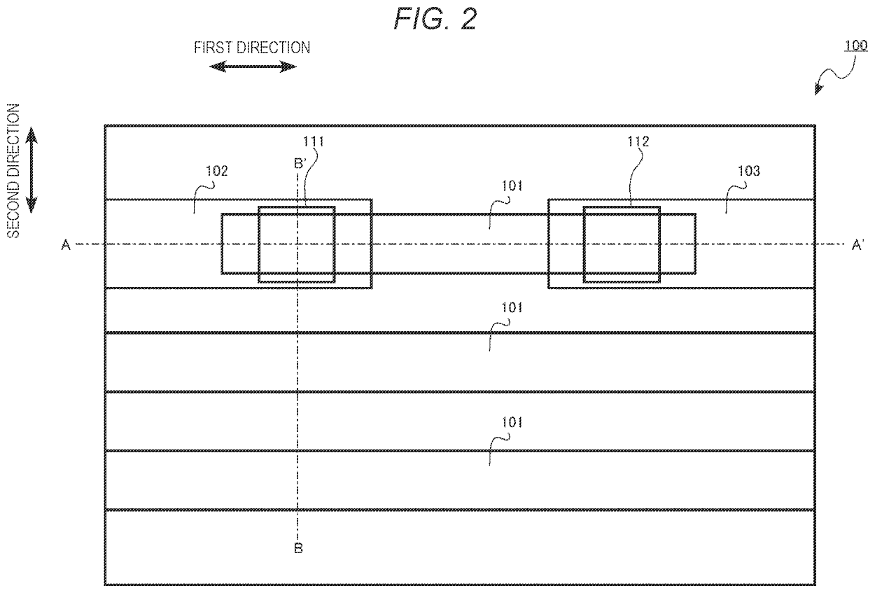

FIG. 1 is a schematic cross-sectional view of a wiring layer of the semiconductor device according to the first embodiment. FIG. 2 is a schematic plan view of the wiring layer of the semiconductor device according to the first embodiment. FIG. 1 is a cross section taken along a line A-A′ of FIG. 2. FIG. 2 illustrates a layout pattern of the wiring layer.

The semiconductor device according to the first embodiment includes a wiring layer 100. The wiring layer 100 includes a first wiring 101, a second wiring 102, a third wiring 103, a first contact plug 111, a second contact plug 112, and an interlayer insulating layer 120.

The second wiring 102 is an example of a second conductive layer. The third wiring 103 is an example of a third conductive layer.

The first wiring 101 is a conductor. The first wiring 101 extends in the first direction.

The second wiring 102 is a conductor. The second wiring 102 extends in the first direction. The second wiring 102 is electrically connected to the first wiring 101.

The first contact plug 111 is a conductor. The first contact plug 111 is disposed between the second wiring 102 and the first wiring 101. The second wiring 102 is electrically connected to the first wiring 101 by using the first contact plug 111.

The third wiring 103 is a conductor. The third wiring 103 extends in the first direction. The third wiring 103 is electrically connected to the first wiring 101.

The second contact plug 112 is a conductor. The second contact plug 112 is disposed between the third wiring 103 and the first wiring 101. The third wiring 103 is electrically connected to the first wiring 101 by using the second contact plug 112.

The second wiring 102 and the third wiring 103 are electrically connected by using the first wiring 101.

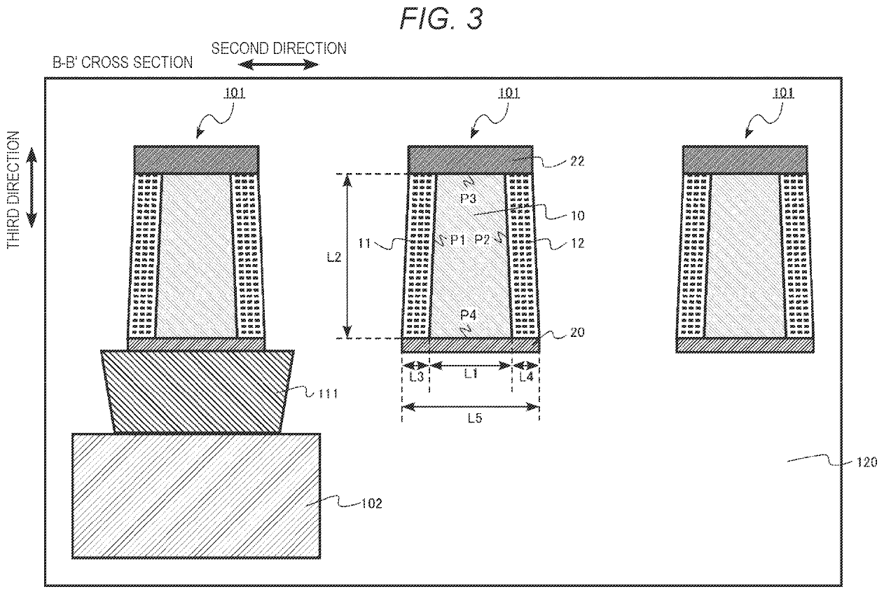

FIG. 3 is a schematic cross-sectional view of the wiring layer of the semiconductor device according to the first embodiment. FIG. 3 is a cross section taken along a line B-B′ of FIG. 2. FIG. 3 is a cross section including the first wiring 101, the second wiring 102, and the first contact plug 111.

The first wiring 101 includes a first conductive layer 10, a first region 11, a second region 12, a conductive film 20, and an insulating film 22. The first wiring 101, the second wiring 102, and the first contact plug 111 are surrounded by the interlayer insulating layer 120.

The first conductive layer 10 extends in the first direction. A direction that intersects the first direction is defined as the second direction. A direction that intersects the first direction and the second direction is defined as the third direction. For example, the second direction is perpendicular to the first direction, and the third direction is perpendicular to the first direction and the second direction.

The first conductive layer 10 includes a first surface P1, a second surface P2, a third surface P3, and a fourth surface P4. The first surface P1 and the second surface P2 are side surfaces of the first conductive layer 10. The third surface P3 is an upper surface of the first conductive layer 10. The fourth surface P4 is a lower surface of the first conductive layer 10.

The first surface P1 is located in the second direction of the first conductive layer 10. The second surface P2 is located in the second direction of the first conductive layer 10. The second surface P2 faces the first surface P1 in the second direction.

The third surface P3 is located in the third direction of the first conductive layer 10. The forth surface P4 is located in the third direction of the first conductive layer 10. The fourth surface P4 faces the third surface P3 in the third direction.

The first conductive layer 10 contains the first element which is at least one element selected from the group consisting of tungsten (W) or molybdenum (Mo). The first element is a metal element. Hereinafter, for the purpose of simplifying the description, the first element, which is at least one element selected from tungsten (W) or molybdenum (Mo) contained in the first conductive layer 10, may be referred to as a main metal element.

A main component of the first conductive layer 10 is the main metal element. That is, among atomic concentrations of elements contained in the first conductive layer 10, the atomic concentration of the main metal element is the highest. The first conductive layer 10 is a metal.

When the main metal element of the first conductive layer 10 is, for example, tungsten (W), the main component of the first conductive layer 10 is tungsten (W). Among the atomic concentrations of the elements contained in the first conductive layer 10, the atomic concentration of tungsten (W) is the highest. When the main metal element of the first conductive layer 10 is, for example, tungsten (W), a ratio of the atomic concentration of tungsten (W) to a total atomic concentration of the elements contained in the first conductive layer 10 is 80% or more. The first conductive layer 10 is, for example, tungsten.

When the main metal element of the first conductive layer 10 is, for example, molybdenum (Mo), the main component of the first conductive layer 10 is molybdenum (Mo). Among the atomic concentrations of the elements contained in the first conductive layer 10, the atomic concentration of molybdenum (Mo) is the highest. When the main metal element of the first conductive layer 10 is, for example, molybdenum (Mo), a ratio of the atomic concentration of molybdenum (Mo) to the total atomic concentration of the elements contained in the first conductive layer 10 is 80% or more. The first conductive layer 10 is, for example, molybdenum.

A first length (L1 in FIG. 3) of the first conductive layer 10 in the second direction is shorter than, for example, a second length (L2 in FIG. 3) of the first conductive layer 10 in the third direction. The first length L1 is the maximum length of the first conductive layer 10 in the second direction.

The first length L1 is, for example, 5 nm or more and 20 nm or less. The second length L2 is, for example, 30 nm or more and 100 nm or less.

The first region 11 is disposed on a first surface P1 side of the first conductive layer 10. The first region 11 is in contact with, for example, the first conductive layer 10. The first region 11 is in contact with, for example, the first surface P1 of the first conductive layer 10.

The first region 11 contains the second element which is at least one element selected from the group consisting of tungsten (W) or molybdenum (Mo), and the third element which is at least one element selected from the group consisting of sulfur (S), selenium (Se), or tellurium (Te). The first element and the second element are the same element. Therefore, the second element is the main metal element. Hereinafter, a case where the third element is sulfur (S) will be described as an example.

The first region 11 contains the main metal element contained in the first conductive layer 10 and sulfur (S). When the main metal element of the first conductive layer 10 is, for example, tungsten (W), the first region 11 contains tungsten (W). When the main metal element of the first conductive layer 10 contains, for example, molybdenum (Mo), the first region 11 contains molybdenum (Mo).

Main components of the first region 11 contain the main metal element and sulfur (S). That is, among elements contained in the first region 11 other than the main metal element and sulfur (S), there is no element having an atomic concentration higher than the atomic concentration of the main metal element. In addition, among the elements contained in the first region 11 other than the main metal element and sulfur (S), there is no element having an atomic concentration higher than the atomic concentration of sulfur (S).

The first region 11 contains, for example, a sulfide of the main metal element. When the main metal element is tungsten (W), the first region 11 contains, for example, tungsten sulfide. When the main metal element is tungsten (W), the first region 11 contains, for example, tungsten disulfide (WS₂). The first region 11 contains, for example, WS₃, WO₂, or WO₃ as an impurity.

When the main metal element is molybdenum (Mo), the first region 11 contains, for example, molybdenum sulfide. When the main metal element is molybdenum (Mo), the first region 11 contains, for example, molybdenum disulfide (MoS₂). The first region 11 contains, for example, Mo₂S₃, MoO₂, or MoO₃ as an impurity.

The first region 11 is crystalline. The first region 11 contains the first crystal. The first crystal contains the main metal element and sulfur (S). The first crystal is a sulfide of the main metal element.

When the main metal element is, for example, tungsten (W), the first crystal contains tungsten (W) and sulfur (S). The first crystal is, for example, tungsten sulfide. The first crystal is, for example, tungsten disulfide.

When the main metal element is, for example, molybdenum (Mo), the first crystal contains molybdenum (Mo) and sulfur (S). The first crystal is, for example, molybdenum sulfide. The first crystal is, for example, molybdenum disulfide.

The first crystal has, for example, a layered structure in which unit layers are stacked in the second direction. The first crystal has, for example, a layered structure in which the unit layers extending in a direction parallel to the first surface P1 are stacked in a direction perpendicular to the first surface P1.

When the first crystal is, for example, tungsten disulfide, each of the unit layers contains tungsten and sulfur. When the first crystal is, for example, molybdenum disulfide, the unit layer contains molybdenum and sulfur.

The first crystal is, for example, a hexagonal crystal. An average direction of the first crystal in a c-axis direction is oriented in a direction perpendicular to an approximate plane of the first surface P1. The average direction of the first crystal in the c-axis direction has an inclination of 10 degrees or less with respect to the direction perpendicular to the approximate plane of the first surface P1.

The first crystal is a two-dimensional crystal. The first crystal includes, for example, a plurality of unit layers of one layer or more and ten layers or less. In addition, the first crystal includes, for example, a plurality of unit layers of two layers or more and ten layers or less.

The unit layers of the two-dimensional crystal extend, for example, in the direction parallel to the first surface P1. The two-dimensional crystal has, for example, a layered structure in which the plurality of unit layers are stacked in the second direction. There are no covalent bonds or ionic bonds between the unit layers, and the layered structure is maintained by Van der Waals force.

A third length (L3 in FIG. 3) of the first region 11 in the second direction is shorter than, for example, the length (L1 in FIG. 3) of the first conductive layer 10 in the second direction. The third length L3 is, for example, 0.5 nm or more and 10 nm or less. The third length L3 is the maximum length of the first region 11 in the second direction.

The second region 12 is disposed on a second surface P2 side of the first conductive layer 10. The second region 12 is in contact with, for example, the first conductive layer 10. The second region 12 is in contact with, for example, the second surface P2 of the first conductive layer 10.

The first conductive layer 10 is disposed between the first region 11 and the second region 12.

The second region 12 contains the second element which is at least one element selected from the group consisting of tungsten (W) or molybdenum (Mo), and the third element which is at least one element selected from the group consisting of sulfur (S), selenium (Se), or tellurium (Te). The first element and the second element are the same element. Therefore, the second element is the main metal element. Hereinafter, the case where the third element is sulfur (S) will be described as an example.

The second region 12 contains the main metal element contained in the first conductive layer 10 and sulfur (S). When the main metal element of the first conductive layer 10 is, for example, tungsten (W), the second region 12 contains tungsten (W). When the main metal element of the first conductive layer is, for example, molybdenum (Mo), the second region 12 contains molybdenum (Mo).

Main components of the second region 12 contain the main metal element and sulfur (S). That is, among elements contained in the second region 12 other than the main metal element and sulfur (S), there is no element having an atomic concentration higher than the atomic concentration of the main metal element. In addition, among the elements contained in the second region 12 other than the main metal element and sulfur (S), there is no element having an atomic concentration higher than the atomic concentration of sulfur (S).

The second region 12 contains, for example, the sulfide of the main metal element. When the main metal element is tungsten (W), the second region 12 contains, for example, tungsten sulfide. When the main metal element is tungsten (W), the second region 12 contains, for example, tungsten disulfide (WS₂). The second region 12 contains, for example, WS₃, WO₂, or WO₃ as an impurity.

When the main metal element is molybdenum (Mo), the second region 12 contains, for example, molybdenum sulfide. When the main metal element is molybdenum (Mo), the second region 12 contains, for example, molybdenum disulfide (MoS₂). The second region 12 contains, for example, Mo₂S₃, MoO₂, or MoO₃ as an impurity.

The second region 12 is crystalline. The second region 12 contains the second element. The second crystal contains the main metal element and sulfur (S). The second crystal is a sulfide of the main metal element.

When the main metal element is, for example, tungsten (W), the second crystal contains tungsten (W) and sulfur (S). The second crystal is, for example, tungsten sulfide. The second crystal is, for example, tungsten disulfide.

When the main metal element is, for example, molybdenum (Mo), the second crystal contains molybdenum (Mo) and sulfur (S). The second crystal is, for example, molybdenum sulfide. The second crystal is, for example, molybdenum disulfide.

The second crystal has, for example, a layered structure in which the unit layers are stacked in the second direction. The second crystal has, for example, a layered structure in which the unit layers extending in a direction parallel to the second surface P2 are stacked in a direction perpendicular to the second surface P2.

When the second crystal is, for example, tungsten disulfide, each of the unit layers contains tungsten and sulfur. When the second crystal is, for example, molybdenum disulfide, the unit layer contains molybdenum and sulfur.

The second crystal is, for example, a hexagonal crystal. An average direction of the second crystal in the c-axis direction is oriented in a direction perpendicular to an approximate plane of the second surface P2. The average direction of the second crystal in the c-axis direction has an inclination of 10 degrees or less with respect to the direction perpendicular to the approximate plane of the second surface P2.

The second crystal is a two-dimensional crystal. The second crystal includes, for example, a plurality of unit layers of one layer or more and ten layers or less. In addition, the second crystal includes, for example, a plurality of unit layers of two layers or more and ten layers or less.

The unit layers of the two-dimensional crystal extend, for example, in the direction parallel to the second surface P2. The two-dimensional crystal has, for example, a layered structure in which the plurality of unit layers are stacked in the second direction.

A fourth length (L4 in FIG. 3) of the second region 12 in the second direction is shorter than, for example, the length (L1 in FIG. 3) of the first conductive layer 10 in the second direction. The fourth length L4 is, for example, 0.5 nm or more and 10 nm or less. The fourth length L4 is the maximum length of the second region 12 in the second direction.

The conductive film 20 is disposed on a fourth surface P4 side of the first conductive layer 10. The conductive film 20 is in contact with, for example, the first conductive layer 10. The conductive film 20 is in contact with, for example, the fourth surface P4.

A chemical composition of the conductive film 20 is different from a chemical composition of the first conductive layer 10. The conductive film 20 is, for example, a metal or a metal nitride. The conductive film 20 is, for example, titanium, titanium nitride, tantalum, tantalum nitride, or tungsten nitride. A part of the conductive film 20 is, for example, a sulfide, a selenium product, or a tellurium product.

The conductive film 20 has, for example, a function of improving adhesion of the first wiring 101 to the interlayer insulating layer 120.

A fifth length (L5 in FIG. 3) of the conductive film 20 in the second direction is longer than, for example, the length (L1 in FIG. 3) of the first conductive layer 10 in the second direction. The fifth length L5 is a length of the uppermost surface of the conductive film 20 in the second direction.

The insulating film 22 is disposed on a third surface P3 side of the first conductive layer 10. The insulating film 22 is in contact with, for example, the first conductive layer 10. The insulating film 22 is in contact with, for example, the third surface P3.

The insulating film 22 is, for example, silicon oxide, silicon nitride, or silicon oxynitride. For example, the insulating film 22 is used as a hard mask during processing of the first wiring 101.

Next, a method for manufacturing the semiconductor device according to the first embodiment will be described. In particular, an example of a method for manufacturing the first wiring 101 will be described.

In the method for manufacturing the semiconductor device according to the first embodiment, a conductive layer containing at least one metal element selected from the group consisting of tungsten (W) or molybdenum (Mo) is formed, the conductive layer is patterned, and a first heat treatment is performed so as to sulfurize a surface of the patterned conductive layer. Hereinafter, a case where the main metal element is tungsten (W) will be described as an example.

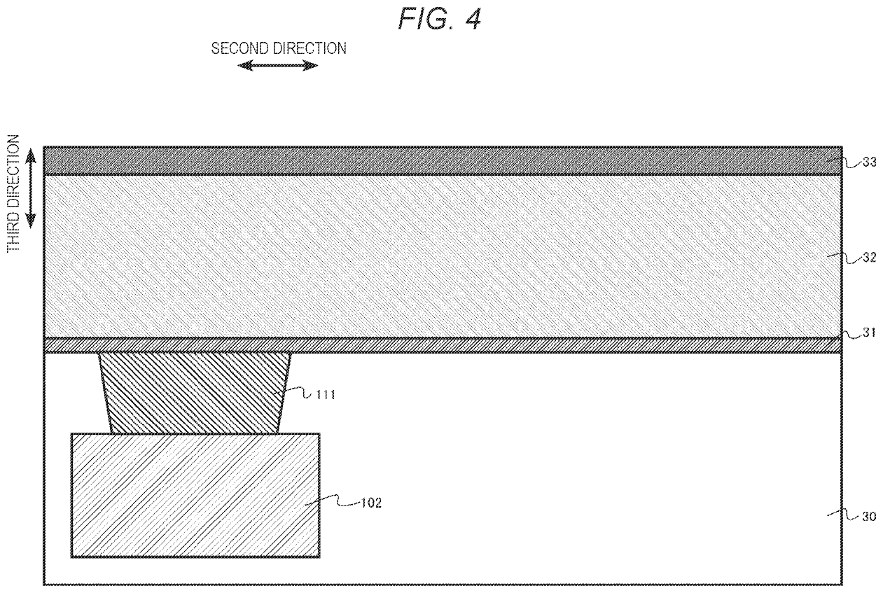

FIGS. 4, 5, 6, 7, and 8 are schematic cross-sectional views illustrating the method for manufacturing the semiconductor device according to the first embodiment.

First, a conductive film 31, a tungsten layer 32, and an insulating film 33 are formed on an insulating layer 30 (FIG. 4). In the insulating layer 30, for example, the second wiring 102 and the first contact plug 111 are formed. The insulating layer 30 is, for example, a silicon oxide layer.

The conductive film 31 is, for example, a titanium nitride film formed by a sputtering method. The tungsten layer 32 is formed by, for example, the sputtering method. The insulating film 33 is, for example, a silicon nitride film formed by a chemical vapor deposition method (CVD method). The tungsten layer 32 is an example of the conductive layer.

The insulating layer 30 finally becomes a part of the interlayer insulating layer 120. A part of the conductive film finally becomes the conductive film 20. A part of the tungsten layer 32 finally becomes the first conductive layer 10. A part of the insulating film 33 finally becomes the insulating film 22.

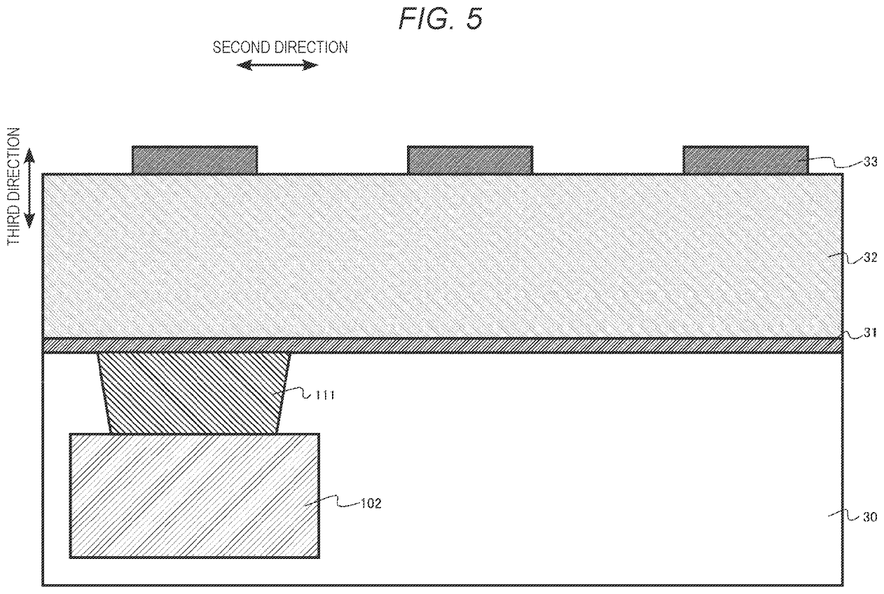

Next, the insulating film 33 is patterned (FIG. 5). The insulating film 33 is patterned by using, for example, a photolithography method and a reactive ion etching method (RIE method).

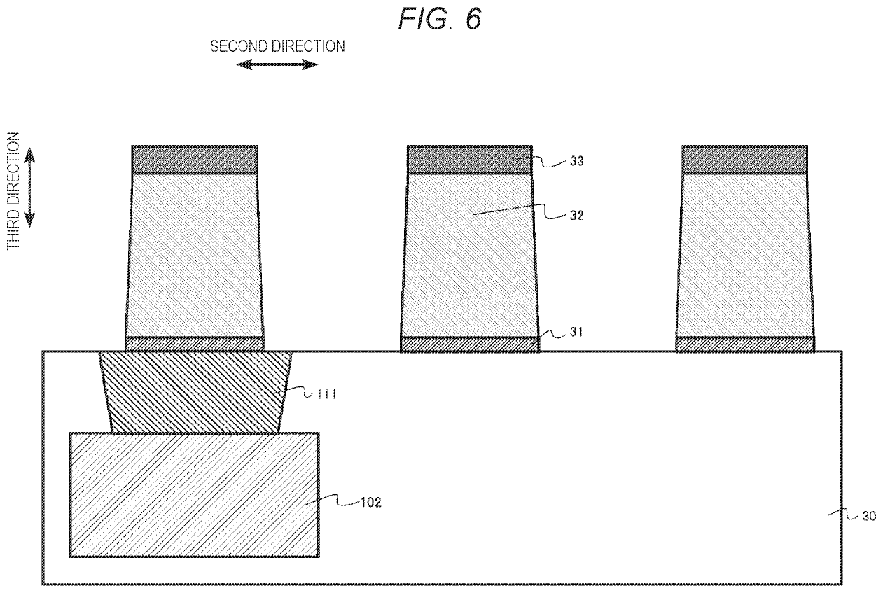

Next, the insulating film 33 is used as a hard mask to pattern the tungsten layer 32 and the conductive film 31 (FIG. 6). The tungsten layer 32 and the conductive film 31 are patterned by using, for example, the RIE method.

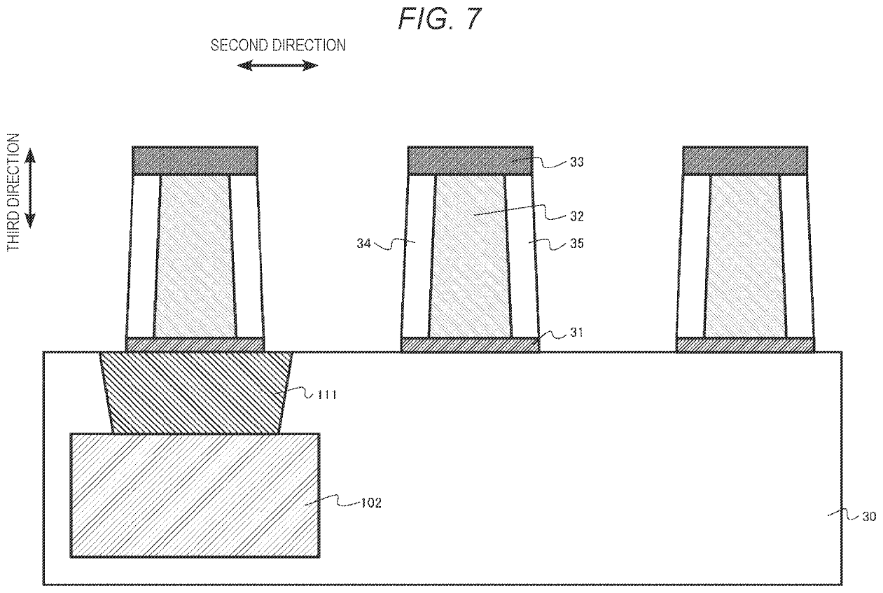

Next, the first heat treatment is performed (FIG. 7). The first heat treatment is performed, for example, in an atmosphere containing plasma of hydrogen sulfide (H₂S). The atmosphere of the first heat treatment contains, for example, argon or hydrogen. The first heat treatment is performed, for example, at a temperature of 300° C. or higher and 500° C. or lower.

By the first heat treatment, a surface of the tungsten layer 32 is sulfurized. By the first heat treatment, side surfaces of the tungsten layer 32 are sulfurized. The tungsten layer 32 is sulfurized to form a first tungsten sulfide region 34 and a second tungsten sulfide region 35.

Further, the first heat treatment is performed, for example, in a hydrogen sulfide gas atmosphere containing no plasma. In this case, the first heat treatment is performed, for example, at a temperature of 450° C. or higher and 800° C. or lower.

The first heat treatment is performed at a temperature of 300° C. or higher and 800° C. or lower in an atmosphere containing the plasma of hydrogen sulfide, and is performed at a temperature of 500° C. or higher and 900° C. or lower in an atmosphere containing a hydrogen sulfide gas and containing no plasma of hydrogen sulfide.

The first tungsten sulfide region 34 finally becomes the first region 11. The second tungsten sulfide region 35 finally becomes the second region 12.

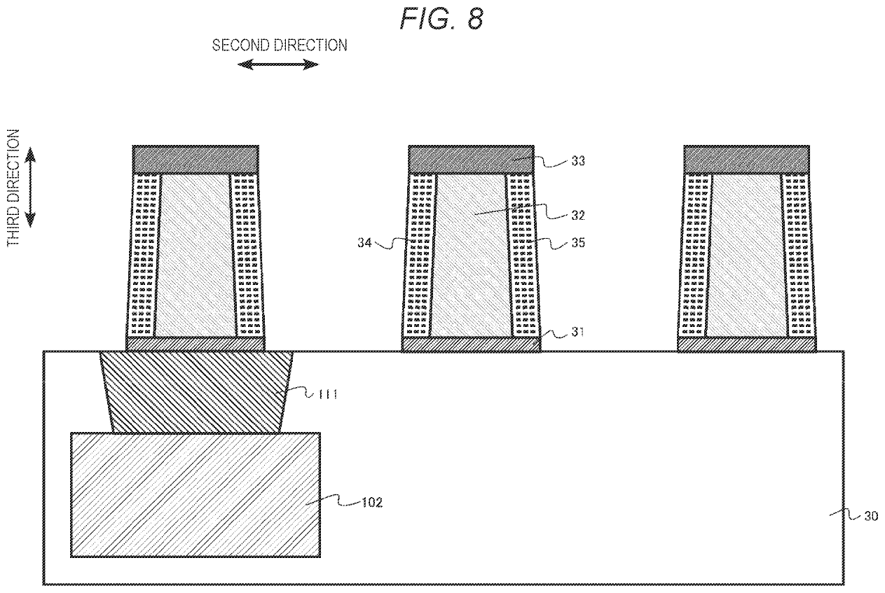

Next, a second heat treatment is performed (FIG. 8). The second heat treatment is performed in a non-oxidizing atmosphere. The non-oxidizing atmosphere contains, for example, argon or nitrogen. The second heat treatment is performed, for example, at a temperature higher than the temperature of the first heat treatment. The second heat treatment is performed, for example, at a temperature of 600° C. or higher and 1000° C. or lower.

By the second heat treatment, crystallization of the first tungsten sulfide region 34 and the second tungsten sulfide region 35 proceeds. By the second heat treatment, the first tungsten sulfide region 34 and the second tungsten sulfide region 35 become two-dimensional crystals having a layered structure.

Further, by the second heat treatment, for example, tungsten oxide films formed on side surfaces of the tungsten layer 32 are volatilized or replaced with tungsten sulfide. Therefore, an interface between the tungsten layer 32 and the first tungsten sulfide region 34 and an interface between the tungsten layer 32 and the second tungsten sulfide region 35 are good interfaces from which the tungsten oxide films are removed.

Then, an insulating layer is formed on the insulating film 33.

The insulating film 33 may be removed after the second heat treatment.

According to the above manufacturing method, the first wiring 101 of the semiconductor device according to the first embodiment is manufactured.

When the main metal element is molybdenum (Mo), the first wiring 101 can be formed by replacing the tungsten layer 32 with a molybdenum layer.

Next, functions and effects of the semiconductor device according to the first embodiment and the manufacturing method thereof will be described.

In association with miniaturization of a semiconductor device, miniaturization of a wiring electrically connecting elements in the semiconductor device is also required. It is desired to achieve a wiring having a low electrical resistance even if a wiring width is reduced.

When the wiring width is reduced, scattering of free electrons on a surface of the wiring is a dominant factor of an increase in electrical resistance. Therefore, it is necessary to prevent the scattering of the free electrons on the surface of the wiring.

The first wiring 101 according to the first embodiment includes the first region 11 on the side surface of the first conductive layer 10, that is, the first surface P1. Further, the first wiring 101 includes the second region 12 on the second surface P2.

The first region 11 is formed of the two-dimensional crystal having a layered structure in which the plurality of unit layers are stacked. Further, the second region 12 is formed of the two-dimensional crystal having a layered structure in which the plurality of unit layers are stacked.

Therefore, the scattering of the free electrons on the side surfaces of the first conductive layer 10 can be prevented. Accordingly, the wiring having a low electrical resistance can be achieved even if the wiring width is reduced.

In the first wiring 101, the first conductive layer 10 and the first region 11, and the first conductive layer 10 and the second region 12 contain the same main metal element. Therefore, the first region 11 and the second region 12 can be formed by sulfurizing a metal material used for forming the first conductive layer 10. Accordingly, the first region 11 and the second region 12 can be easily formed.

In addition, an interface between the first conductive layer 10 and the first region 11 and an interface between the first conductive layer 10 and the second region 12 can be formed as good interfaces from which metal oxides are removed. In particular, by performing the second heat treatment, the removal of metal oxides proceeds, and thus good interfaces can be formed.

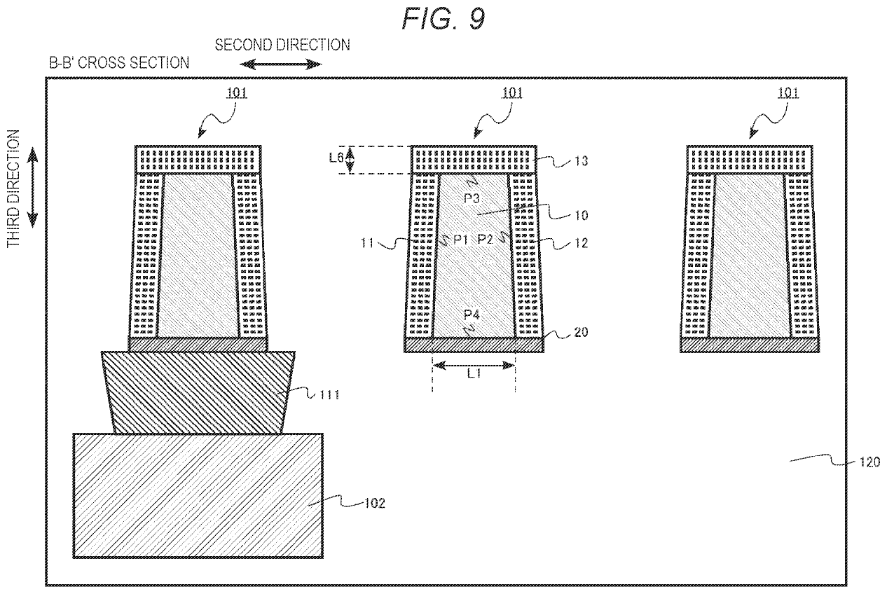

FIG. 9 is a schematic cross-sectional view of a wiring layer of a modification of the semiconductor device according to the first embodiment. FIG. 9 is a diagram corresponding to FIG. 3.

The first wiring 101 of the modification is different from the first wiring 101 according to the first embodiment in that the first wiring 101 of the modification further includes a third region 13 that is disposed on the third surface P3 side of the first conductive layer 10, contains the main metal element and sulfur (S), and includes a third crystal.

The third region 13 is disposed on the third surface P3 side of the first conductive layer 10. The third region 13 is in contact with, for example, the first conductive layer 10. The third region 13 is in contact with, for example, the third surface P3 of the first conductive layer 10.

The first conductive layer 10 is disposed between the third region 13 and the conductive film 20.

The third region 13 contains the second element which is at least one element selected from the group consisting of tungsten (W) or molybdenum (Mo), and the third element which is at least one element selected from the group consisting of sulfur (S), selenium (Se), or tellurium (Te). The first element and the second element are the same element. Therefore, the second element is the main metal element. Hereinafter, the case where the third element is sulfur (S) will be described as an example.

The third region 13 contains the main metal element contained in the first conductive layer 10 and sulfur (S). When the main metal element of the first conductive layer 10 is, for example, tungsten (W), the third region 13 contains tungsten (W). When the main metal element of the first conductive layer is, for example, molybdenum (Mo), the third region 13 contains molybdenum (Mo).

Main components of the third region 13 contain the main metal element and sulfur (S). That is, among elements contained in the third region 13 other than the main metal element and sulfur (S), there is no element having an atomic concentration higher than the atomic concentration of the main metal element. In addition, among the elements contained in the third region 13 other than the main metal element and sulfur (S), there is no element having an atomic concentration higher than the atomic concentration of sulfur (S).

The third region 13 contains, for example, the sulfide of the main metal element. When the main metal element is tungsten (W), the third region 13 contains, for example, tungsten sulfide. When the main metal element is tungsten (W), the third region 13 contains, for example, tungsten disulfide (WS₂). The third region 13 contains, for example, WS₃, WO₂, or WO₃ as an impurity.

When the main metal element is molybdenum (Mo), the third region 13 contains, for example, molybdenum sulfide. When the main metal element is molybdenum (Mo), the third region 13 contains, for example, molybdenum disulfide (MoS₂). The third region 13 contains, for example, Mo₂S₃, MoO₂, or MoO₃ as an impurity.

The third region 13 is crystalline. The third region 13 contains the third crystal. The third crystal contains the main metal element and sulfur (S). The third crystal is a sulfide of the main metal element.

When the main metal element is, for example, tungsten (W), the third crystal contains tungsten (W) and sulfur (S). The third crystal is, for example, tungsten sulfide. The third crystal is, for example, tungsten disulfide.

When the main metal element is, for example, molybdenum (Mo), the third crystal contains molybdenum (Mo) and sulfur (S). The third crystal is, for example, molybdenum sulfide. The third crystal is, for example, molybdenum disulfide.

The third crystal has, for example, a layered structure in which the unit layers are stacked in the third direction. The third crystal has, for example, a layered structure in which the unit layers extending in a direction parallel to the third surface P3 are stacked in a direction perpendicular to the third surface P3.

The third crystal is, for example, a hexagonal crystal. An average direction of the third crystal in the c-axis direction is oriented in a direction perpendicular to an approximate plane of the third surface P3. The average direction of the third crystal in the c-axis direction has an inclination of 10 degrees or less with respect to the direction perpendicular to the approximate plane of the third surface P3.

The third crystal is a two-dimensional crystal. The third crystal includes, for example, a plurality of unit layers of one layer or more and ten layers or less. In addition, the third crystal includes, for example, a plurality of unit layers of two layers or more and ten layers or less.

The unit layers of the two-dimensional crystal extend, for example, in the direction parallel to the third surface P3. The two-dimensional crystal has, for example, a layered structure in which the plurality of unit layers are stacked in the third direction.

A sixth length (L6 in FIG. 9) of the third region 13 in the third direction is shorter than, for example, the length (L1 in FIG. 9) of the first conductive layer 10 in the second direction. The sixth length L6 is, for example, 0.5 nm or more and 10 nm or less.

Since the first wiring 101 of the modification includes the third region 13, it is possible to prevent the scattering of the free electrons on the upper surface of the first conductive layer 10. Therefore, a wiring having a lower electrical resistance can be achieved even if the wiring width is reduced. Further, the wiring having a low electrical resistance can be achieved even if a thickness of the wiring is reduced.

Although the case where the third element is sulfur (S) is described above as an example, the third element may be selenium (Se) or tellurium (Te).

Although the side surfaces of the first wiring 101 form a forward tapered shape in FIGS. 3 and 9, the side surfaces of the first wiring 101 may form, for example, a vertical shape or a reverse tapered shape.

As described above, according to the first embodiment, it is possible to provide a semiconductor device provided with a wiring that prevents the scattering of the free electrons on the surface of the wiring and has a low electrical resistance even if the wiring width is reduced.

### Second Embodiment

A semiconductor device according to a second embodiment is manufactured by a manufacturing method different from that of the semiconductor device according to the first embodiment. In addition, the semiconductor device according to the second embodiment is different from the semiconductor device according to the first embodiment in that the first element and the second element may be different elements. Hereinafter, a part of a description of contents overlapping with that of the first embodiment will be omitted.

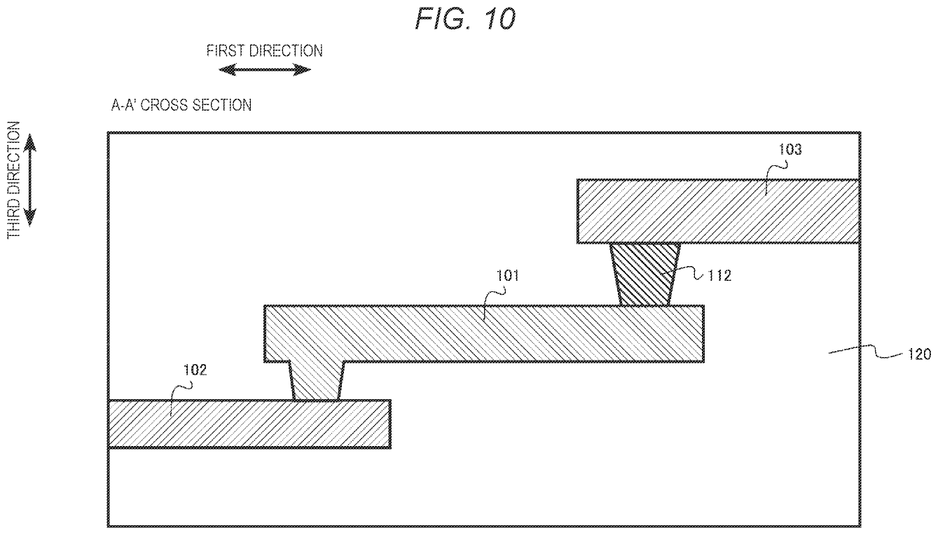

FIG. 10 is a schematic cross-sectional view of a wiring layer of the semiconductor device according to the second embodiment. FIG. 10 is a diagram corresponding to FIG. 1 according to the first embodiment. FIG. 10 is a diagram corresponding to the cross section taken along the line A-A′ of FIG. 2 according to the first embodiment.

The semiconductor device according to the second embodiment includes the first wiring 101, the second wiring 102, the third wiring 103, the second contact plug 112, and the interlayer insulating layer 120. A part of the first wiring 101 is in contact with the second wiring 102. The part of the first wiring 101 has the same function as that of the first contact plug 111 of the semiconductor device according to the first embodiment. The part of the first wiring 101 functions as a contact plug portion.

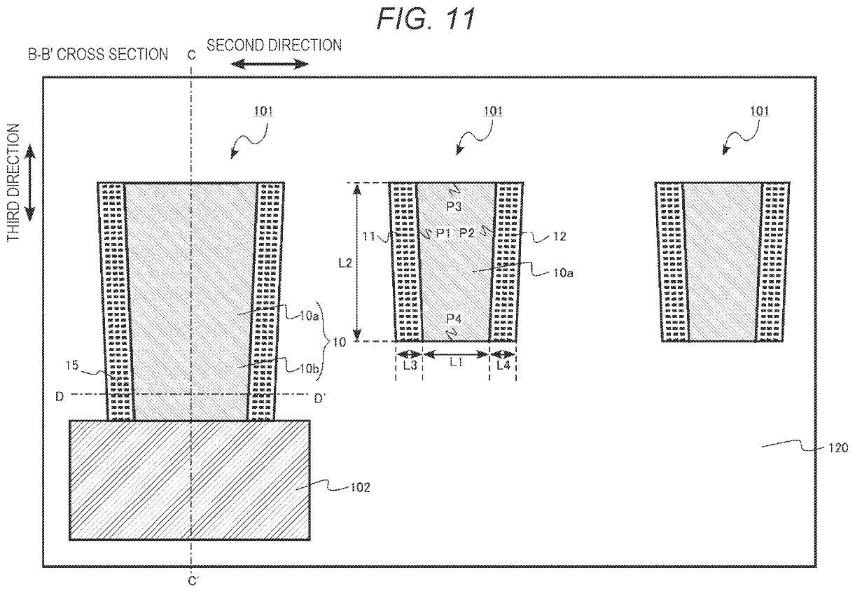

FIG. 11 is a schematic cross-sectional view of the wiring layer of the semiconductor device according to the second embodiment. FIG. 11 is a diagram corresponding to FIG. 3 according to the first embodiment. FIG. 11 is a diagram corresponding to the cross section taken along the line B-B′ of FIG. 2 according to the first embodiment. FIG. 11 is a cross section including the first wiring 101 and the second wiring 102.

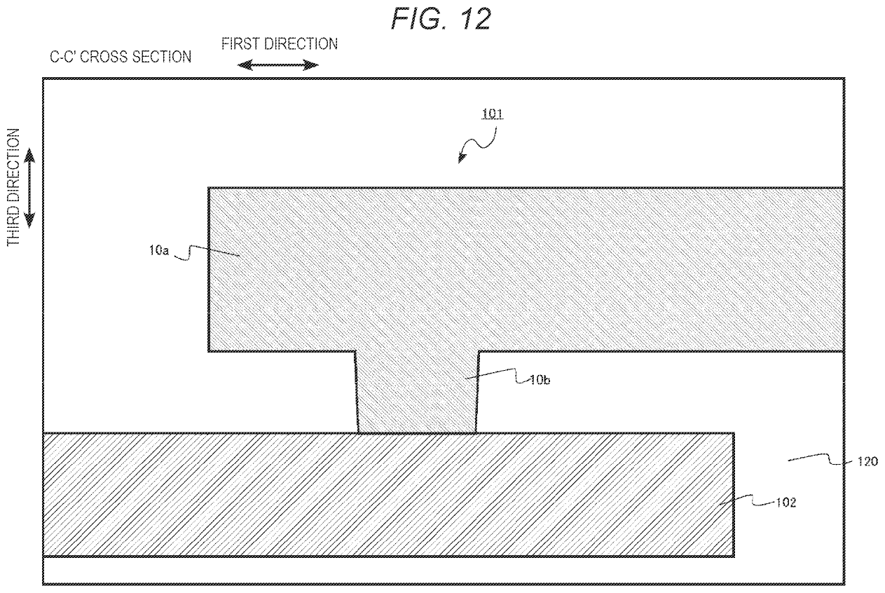

FIG. 12 is a schematic cross-sectional view of the wiring layer of the semiconductor device according to the second embodiment. FIG. 12 is a cross section taken along a line C-C′ of FIG. 11.

The first wiring 101 includes the first conductive layer 10, the first region 11, and the second region 12. The first wiring 101 and the second wiring 102 are surrounded by the interlayer insulating layer 120.

The first conductive layer 10 includes a first portion 10a and a second portion 10b. The first portion 10a extends in a first direction.

A direction that intersects the first direction is defined as a second direction. A direction that intersects the first direction and the second direction is defined as a third direction. For example, the second direction is perpendicular to the first direction, and the third direction is perpendicular to the first direction and the second direction.

The first portion 10a includes the first surface P1, the second surface P2, the third surface P3, and the fourth surface P4. The first surface P1 and the second surface P2 are side surfaces of the first portion 10a. The third surface P3 is an upper surface of the first portion 10a. The fourth surface P4 is a lower surface of the first portion 10a.

The first surface P1 is located in the second direction of the first portion 10a. The second surface P2 is located in the second direction of the first portion 10a. The second surface P2 faces the first surface P1 in the second direction.

The third surface P3 is located in the third direction of the first portion 10a. The fourth surface P4 is located in the third direction of the first portion 10a. The fourth surface P4 faces the third surface P3 in the third direction.

The second portion 10b is disposed between the first portion 10a and the second wiring 102. The second portion 10b is in contact with the second wiring 102. The second portion 10b has the same function as that of the first contact plug 111 according to the first embodiment. The second portion 10b is, for example, a columnar extending in the third direction.

The first conductive layer 10 contains a first element which is at least one element selected from a group consisting of tungsten (W) or molybdenum (Mo). The first element is a metal element.

A main component of the first conductive layer 10 is the first element. That is, among atomic concentrations of elements contained in the first conductive layer 10, the atomic concentration of the first element is the highest. The first conductive layer 10 is a metal.

When the first element of the first conductive layer 10 is, for example, tungsten (W), the main component of the first conductive layer 10 contains tungsten (W). Among the atomic concentrations of the elements contained in the first conductive layer 10, the atomic concentration of tungsten (W) is the highest. When the first element of the first conductive layer is, for example, tungsten (W), a ratio of the atomic concentration of tungsten (W) to a total atomic concentration of the elements contained in the first conductive layer 10 is 80% or more. The first conductive layer 10 is, for example, tungsten.

When the first element of the first conductive layer 10 is, for example, molybdenum (Mo), the main component of the first conductive layer 10 is molybdenum (Mo). Among the atomic concentrations of the elements contained in the first conductive layer 10, the atomic concentration of molybdenum (Mo) is the highest. When the first element of the first conductive layer is, for example, molybdenum (Mo), a ratio of the atomic concentration of molybdenum (Mo) to the total atomic concentration of the elements contained in the first conductive layer 10 is 80% or more. The first conductive layer 10 is, for example, molybdenum.

A first length (L1 in FIG. 11) of the first portion 10a in the second direction is, for example, shorter than a second length (L2 in FIG. 11) of the first portion 10a in the third direction.

The first length L1 is, for example, 5 nm or more and 20 nm or less. The second length L2 is, for example, 30 nm or more and 100 nm or less.

The first region 11 is disposed on a first surface P1 side of the first portion 10a. The first region 11 is in contact with, for example, the first portion 10a. The first region 11 is in contact with, for example, the first surface P1 of the first portion 10a.

The first region 11 contains a second element which is at least one element selected from a group consisting of tungsten (W) or molybdenum (Mo), and a third element which is at least one element selected from a group consisting of sulfur (S), selenium (Se), or tellurium (Te). The first element and the second element may be the same element or different elements. Hereinafter, a case where the third element is sulfur (S) will be described as an example.

Main components of the first region 11 contain the second element and sulfur (S). That is, among elements contained in the first region 11 other than the second element and sulfur (S), there is no element having an atomic concentration higher than the atomic concentration of the second element. In addition, among the elements contained in the first region 11 other than the second element and sulfur (S), there is no element having an atomic concentration higher than the atomic concentration of sulfur (S).

The first region 11 contains, for example, a sulfide of the second element. When the second element is tungsten (W), the first region 11 contains, for example, tungsten sulfide. When the second element is tungsten (W), the first region 11 contains, for example, tungsten disulfide (WS₂). The first region 11 contains, for example, WS₃, WO₂, or WO₃ as an impurity.

When the second element is molybdenum (Mo), the first region 11 contains, for example, molybdenum sulfide. When the second element is molybdenum (Mo), the first region 11 contains, for example, molybdenum disulfide (MoS₂). The first region 11 contains, for example, Mo₂S₃, MoO₂, or MoO₃ as an impurity.

The first region 11 is crystalline. The first region 11 contains a first crystal. The first crystal contains the second element and sulfur (S). The first crystal is a sulfide of the second element.

When the second element is, for example, tungsten (W), the first crystal contains tungsten (W) and sulfur (S). The first crystal is, for example, tungsten sulfide. The first crystal is, for example, tungsten disulfide.

When the second element is, for example, molybdenum (Mo), the first crystal contains molybdenum (Mo) and sulfur (S). The first crystal is, for example, molybdenum sulfide. The first crystal is, for example, molybdenum disulfide.

The first crystal has, for example, a layered structure in which unit layers are stacked in the second direction. The first crystal has, for example, a layered structure in which the unit layers extending in a direction parallel to the first surface P1 are stacked in a direction perpendicular to the first surface P1.

When the first crystal is, for example, tungsten disulfide, each of the unit layers contains tungsten and sulfur. When the first crystal is, for example, molybdenum disulfide, the unit layer contains molybdenum and sulfur.

The first crystal is, for example, a hexagonal crystal. An average direction of the first crystal in a c-axis direction is oriented in a direction perpendicular to an approximate plane of the first surface P1. The average direction of the first crystal in the c-axis direction has an inclination of 10 degrees or less with respect to the direction perpendicular to the approximate plane of the first surface P1.

The first crystal is a two-dimensional crystal. The first crystal includes, for example, a plurality of unit layers of one layer or more and ten layers or less. In addition, the first crystal includes, for example, a plurality of unit layers of two layers or more and ten layers or less.

The unit layers of the two-dimensional crystal extend, for example, in the direction parallel to the first surface P1. The two-dimensional crystal has, for example, a layered structure in which the plurality of unit layers are stacked in the second direction. There are no covalent bonds or ionic bonds between the unit layers, and the layered structure is maintained by Van der Waals force.

A third length (L3 in FIG. 11) of the first region 11 in the second direction is shorter than, for example, the length (L1 in FIG. 11) of the first portion 10a in the second direction. The third length L3 is, for example, 0.5 nm or more and 10 nm or less.

The second region 12 is disposed on a second surface P2 side of the first portion 10a. The second region 12 is in contact with, for example, the first portion 10a. The second region 12 is in contact with, for example, the second surface P2 of the first portion 10a.

The first portion 10a is disposed between the first region 11 and the second region 12.

The second region 12 contains the second element which is at least one element selected from the group consisting of tungsten (W) or molybdenum (Mo), and the third element which is at least one element selected from the group consisting of sulfur (S), selenium (Se), or tellurium (Te). The first element and the second element may be the same element or different elements. Hereinafter, the case where the third element is sulfur (S) will be described as an example.

Main components of the second region 12 contain the second element and sulfur (S). That is, among elements contained in the second region 12 other than the second element and sulfur (S), there is no element having an atomic concentration higher than the atomic concentration of the second element. In addition, among the elements contained in the second region 12 other than the second element and sulfur (S), there is no element having an atomic concentration higher than the atomic concentration of sulfur (S).

The second region 12 contains, for example, the sulfide of the second element. When the second element is tungsten (W), the second region 12 contains, for example, tungsten sulfide. When the second element is tungsten (W), the second region 12 contains, for example, tungsten disulfide (WS₂). The second region 12 contains, for example, WS, WS₃, WO₂ or WO₃ as an impurity.

When the second element is molybdenum (Mo), the second region 12 contains, for example, molybdenum sulfide. When the second element is molybdenum (Mo), the second region 12 contains, for example, molybdenum disulfide (MoS₂). The second region 12 contains, for example, MoS, MoO₃ or MO₂S₃ as an impurity.

The second region 12 is crystalline. The second region 12 contains a second crystal. The second crystal contains the second element and sulfur (S). The second crystal is a sulfide of the second element.

When the second element is, for example, tungsten (W), the second crystal contains tungsten (W) and sulfur (S). The second crystal is, for example, tungsten sulfide. The second crystal is, for example, tungsten disulfide.

When the second element is, for example, molybdenum (Mo), the second crystal contains molybdenum (Mo) and sulfur (S). The second crystal is, for example, molybdenum sulfide. The second crystal is, for example, molybdenum disulfide.

The second crystal has, for example, a layered structure in which the unit layers are stacked in the second direction. The second crystal has, for example, a layered structure in which the unit layers extending in a direction parallel to the second surface P2 are stacked in a direction perpendicular to the second surface P2.

When the second crystal is, for example, tungsten disulfide, each of the unit layers contains tungsten and sulfur. When the second crystal is, for example, molybdenum disulfide, the unit layer contains molybdenum and sulfur.

The second crystal is, for example, a hexagonal crystal. An average direction of the second crystal in the c-axis direction is oriented in a direction perpendicular to an approximate plane of the second surface P2. The average direction of the second crystal in the c-axis direction has an inclination of 10 degrees or less with respect to the direction perpendicular to the approximate plane of the second surface P2.

The second crystal is a two-dimensional crystal. The second crystal includes, for example, a plurality of unit layers of one layer or more and ten layers or less. In addition, the second crystal includes, for example, a plurality of unit layers of two layers or more and ten layers or less.

The unit layers of the two-dimensional crystal extend, for example, in the direction parallel to the second surface P2. The two-dimensional crystal has, for example, a layered structure in which the plurality of unit layers are stacked in the second direction.

A fourth length (L4 in FIG. 11) of the second region 12 in the second direction is shorter than, for example, the length (L1 in FIG. 11) of the first portion 10a in the second direction. The fourth length L4 is, for example, 0.5 nm or more and 10 nm or less.

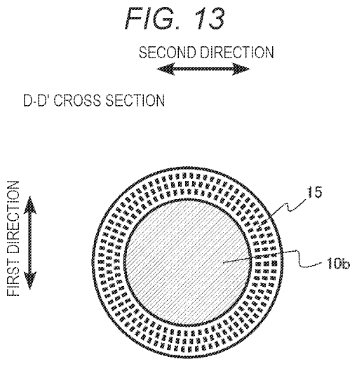

FIG. 13 is a schematic cross-sectional view of the wiring layer of the semiconductor device according to the second embodiment. FIG. 13 is a diagram corresponding to a cross section taken along a line D-D′ of FIG. 11. FIG. 13 is a cross-section including the second portion 10b of the first conductive layer 10.

A fifth region 15 surrounds the second portion 10b. The fifth region 15 is disposed around the second portion 10b. The fifth region 15 is in contact with the second portion 10b.

The fifth region 15 contains the second element which is at least one element selected from the group consisting of tungsten (W) or molybdenum (Mo), and the third element which is at least one element selected from the group consisting of sulfur (S), selenium (Se), or tellurium (Te). The first element and the second element may be the same element or different elements. Hereinafter, the case where the third element is sulfur (S) will be described as an example.

Main components of the fifth region 15 contain the second element and sulfur (S). That is, among elements contained in the fifth region 15 other than the second element and sulfur (S), there is no element having an atomic concentration higher than the atomic concentration of the second element. In addition, among the elements contained in the fifth region 15 other than the second element and sulfur (S), there is no element having an atomic concentration higher than the atomic concentration of sulfur (S).

The fifth region 15 contains, for example, the sulfide of the second element. When the second element is tungsten (W), the fifth region 15 contains, for example, tungsten sulfide. When the second element is tungsten (W), the fifth region 15 contains, for example, tungsten disulfide (WS₂). The fifth region 15 contains, for example, WS₃, WO₂, or WO₃ as an impurity.

When the second element is molybdenum (Mo), the fifth region 15 contains, for example, molybdenum sulfide. When the second element is molybdenum (Mo), the fifth region 15 contains, for example, molybdenum disulfide (MoS₂). The fifth region 15 contains, for example, Mo₂S₃, MoO₂, or MoO₃ as an impurity.

The fifth region 15 is crystalline. The fifth region 15 contains a fifth crystal. The fifth crystal contains the second element and sulfur (S). The fifth crystal is a sulfide of the second element.

When the second element is, for example, tungsten (W), the fifth crystal contains tungsten (W) and sulfur (S). The fifth crystal is, for example, tungsten sulfide. The fifth crystal is, for example, tungsten disulfide.

When the second element is, for example, molybdenum (Mo), the fifth crystal contains molybdenum (Mo) and sulfur (S). The fifth crystal is, for example, molybdenum sulfide. The fifth crystal is, for example, molybdenum disulfide.

The fifth crystal has, for example, a layered structure in which the unit layers extending in a direction parallel to a side surface of the second portion 10b are stacked in a direction perpendicular to the side surface of the second portion 10b.

When the fifth crystal is, for example, tungsten disulfide, each of the unit layers contains tungsten and sulfur. When the fifth crystal is, for example, molybdenum disulfide, the unit layer contains molybdenum and sulfur.

The fifth crystal is a two-dimensional crystal. The fifth crystal includes, for example, a plurality of unit layers of one layer or more and ten layers or less. In addition, the fifth crystal includes, for example, a plurality of unit layers of two layers or more and ten layers or less.

Next, a method for manufacturing the semiconductor device according to the second embodiment will be described. In particular, an example of a method for manufacturing the first wiring 101 will be described. Hereinafter, a case where the first element is tungsten (W), the second element is molybdenum (Mo), and the third element is sulfur (S) will be described as an example.

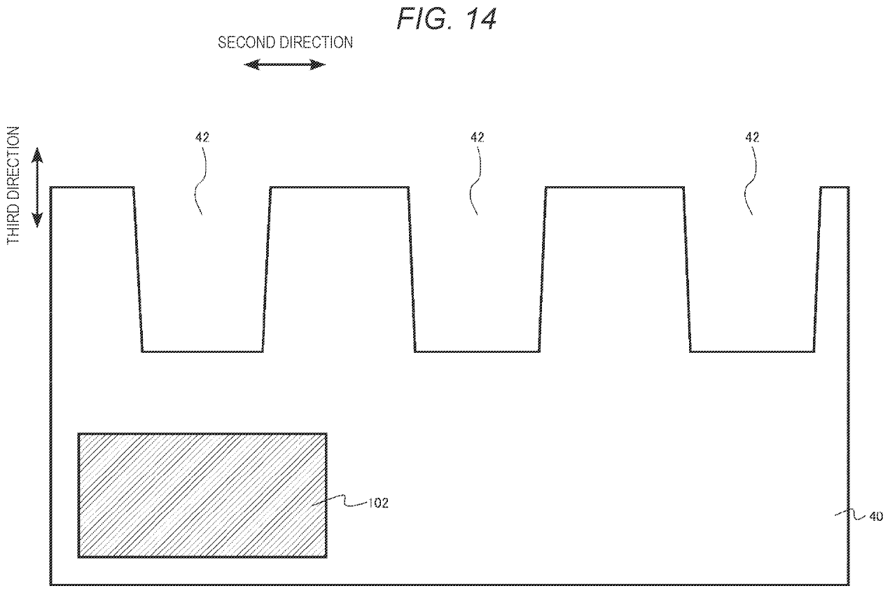

FIGS. 14, 15, 16, 17, 18, 19, and 20 are schematic cross-sectional views illustrating the method for manufacturing the semiconductor device according to the second embodiment.

First, grooves 42 are formed in an insulating layer 40 (FIG. 14). Each of the grooves 42 is formed by using, for example, a photolithography method and a RIE method. The groove 42 extends in the first direction.

In the insulating layer 40, for example, the second wiring 102 is formed. The insulating layer 40 is, for example, a silicon oxide layer. The insulating layer 40 finally becomes a part of the interlayer insulating layer 120.

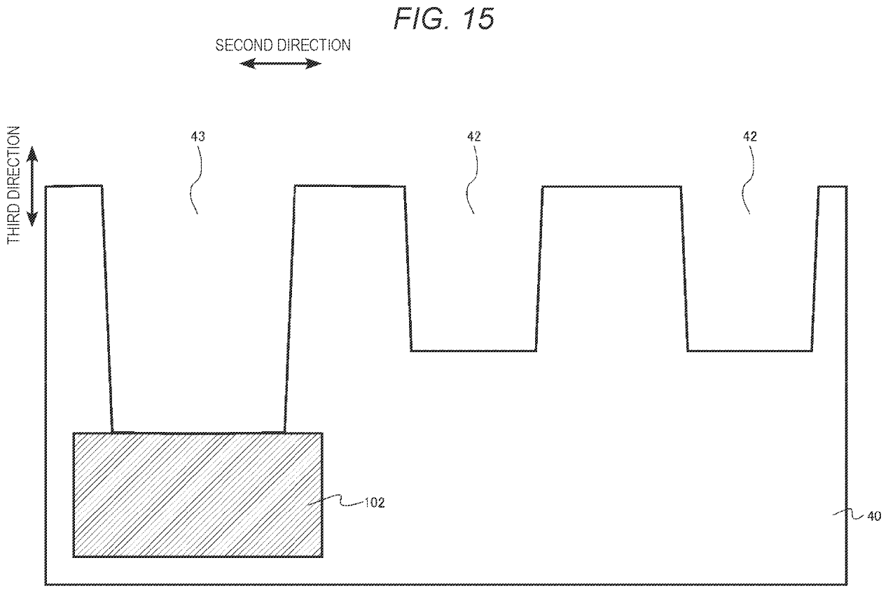

Next, a hole 43 is formed in the insulating layer 40 (FIG. 15). The hole 43 is formed by using, for example, the photolithography method and the RIE method. The hole 43 is formed so that the second wiring 102 is exposed. A width of the hole 43 in the second direction is longer than, for example, a width of the groove 42 in the second direction.

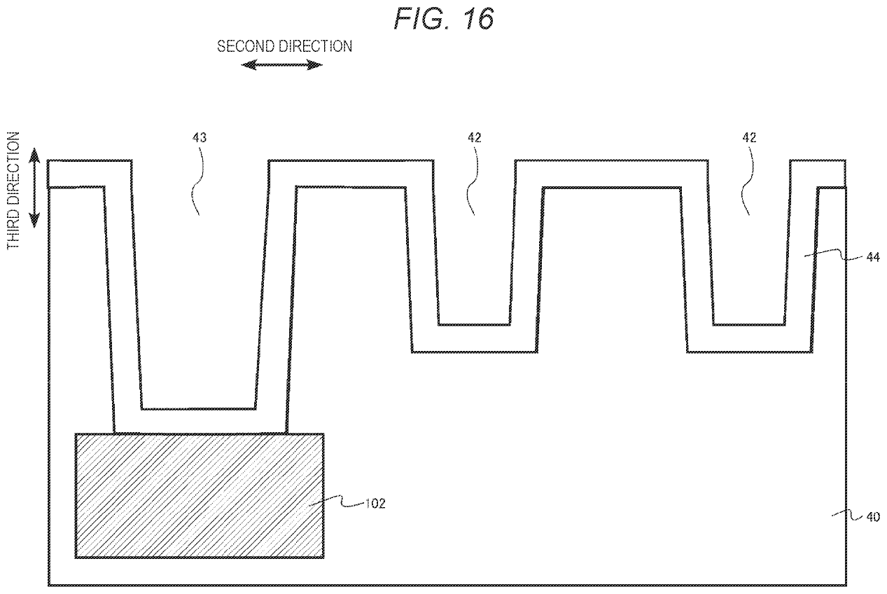

Next, a molybdenum sulfide film 44 is formed in the grooves 42 and the hole 43 (FIG. 16). The molybdenum sulfide film 44 is formed by, for example, a CVD method. The molybdenum sulfide film 44 may also be formed by, for example, sulfurizing a molybdenum film formed by the CVD method.

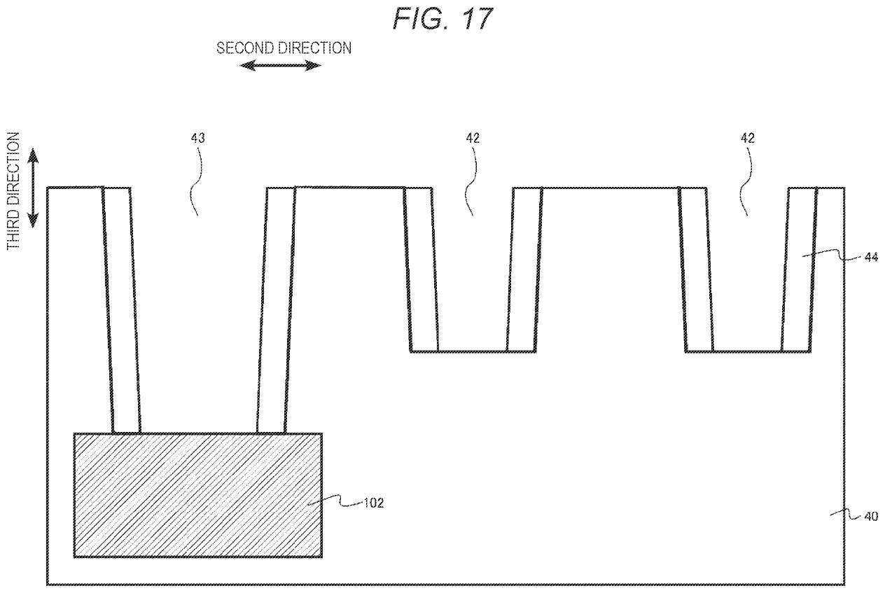

Next, the molybdenum sulfide film 44 at bottoms of the grooves 42 and a bottom of the hole 43 are removed (FIG. 17). The molybdenum sulfide film 44 is removed by, for example, an ion milling method or the RIE method.

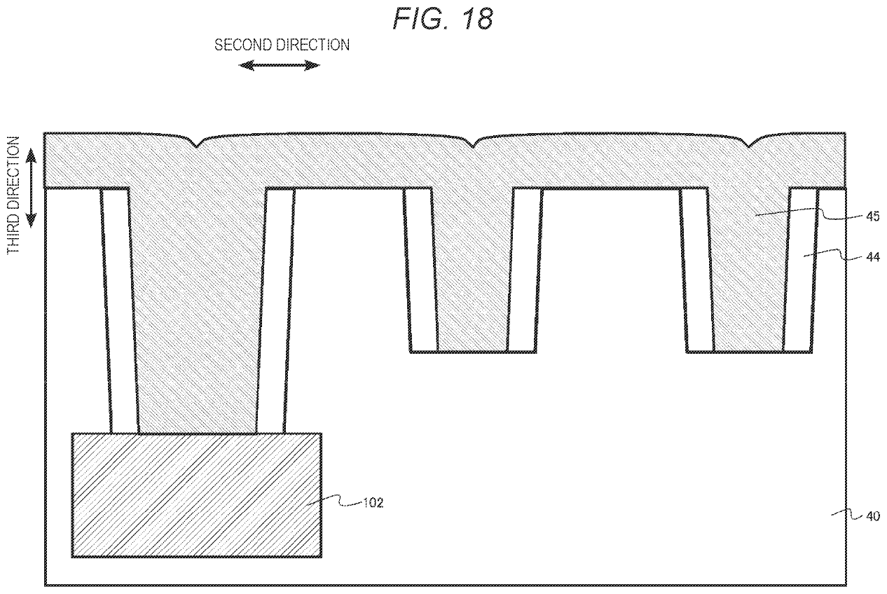

Next, the grooves 42 and the hole 43 are filled therein with a tungsten film 45 (FIG. 18). Tungsten film 45 is formed by using, for example, the CVD method. A part of the tungsten film 45 finally becomes the first conductive layer 10.

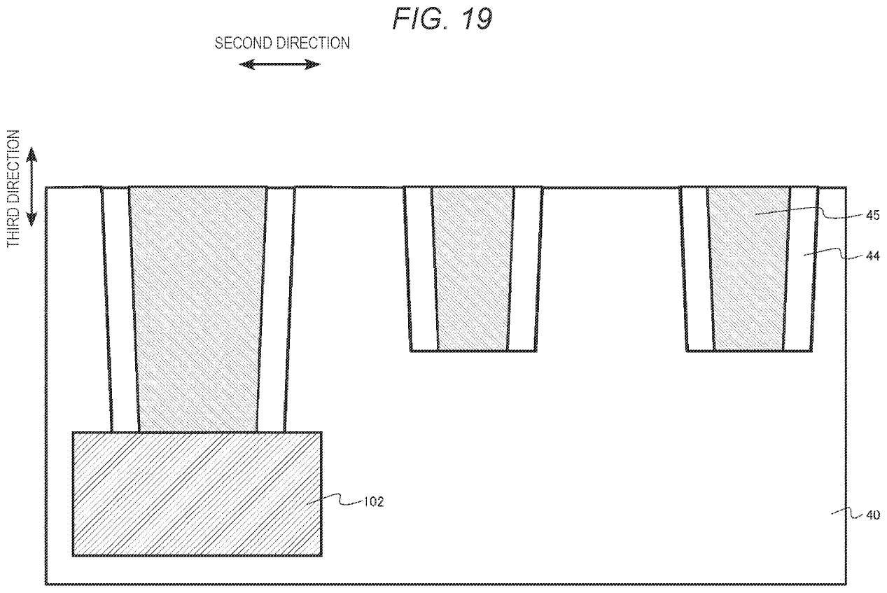

Next, the tungsten film 45 on a surface of the insulating layer 40 is removed (FIG. 19). The tungsten film 45 is removed by using, for example, a chemical mechanical polishing method (CMP method).

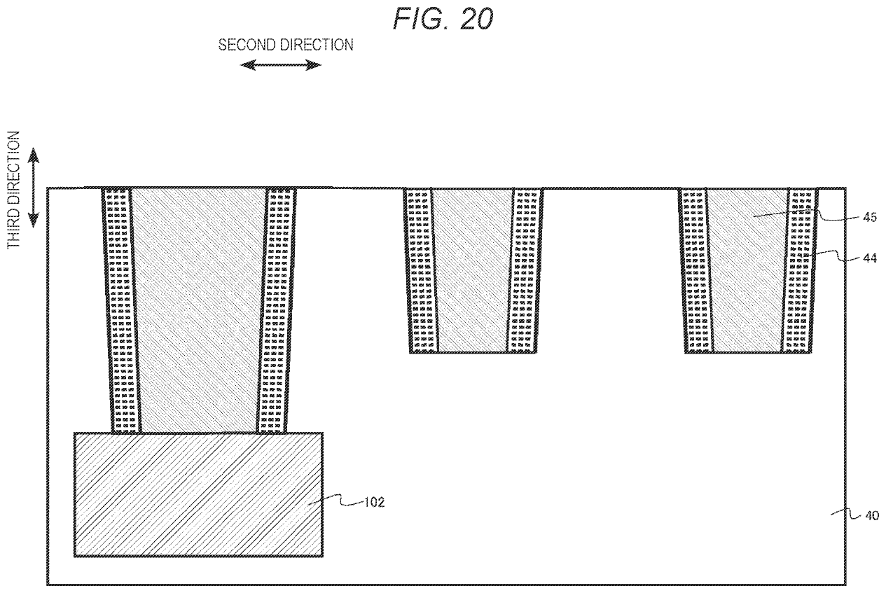

Next, a heat treatment is performed (FIG. 20). The heat treatment is performed in a non-oxidizing atmosphere. The non-oxidizing atmosphere contains, for example, argon or nitrogen. The heat treatment is performed, for example, at a temperature of 600° C. or higher and 1000° C. or lower.

By the heat treatment, crystallization of the molybdenum sulfide film 44 proceeds. By the heat treatment, the molybdenum sulfide film 44 becomes a two-dimensional crystal having a layered structure.

Then, an insulating layer is formed on the insulating layer 40.

According to the above manufacturing method, the first wiring 101 of the semiconductor device according to the second embodiment is manufactured.

When the first element is molybdenum (Mo), the first wiring 101 can be formed by replacing the tungsten film 45 with a molybdenum film. When the second element is tungsten (W), the first wiring 101 can be formed by replacing the molybdenum sulfide film 44 with a tungsten sulfide film.

According to the second embodiment, scattering of free electrons on the side surfaces of the first portion 10a of the first conductive layer 10 can be prevented, as in the first embodiment. Accordingly, a wiring having a low electrical resistance can be achieved even if a wiring width is reduced. In addition, according to the second embodiment, scattering of free electrons on the side surface of the second portion 10b of the first conductive layer 10 can be prevented. Accordingly, it is possible to reduce a wiring resistance of the contact plug portion even if a contact size is reduced.

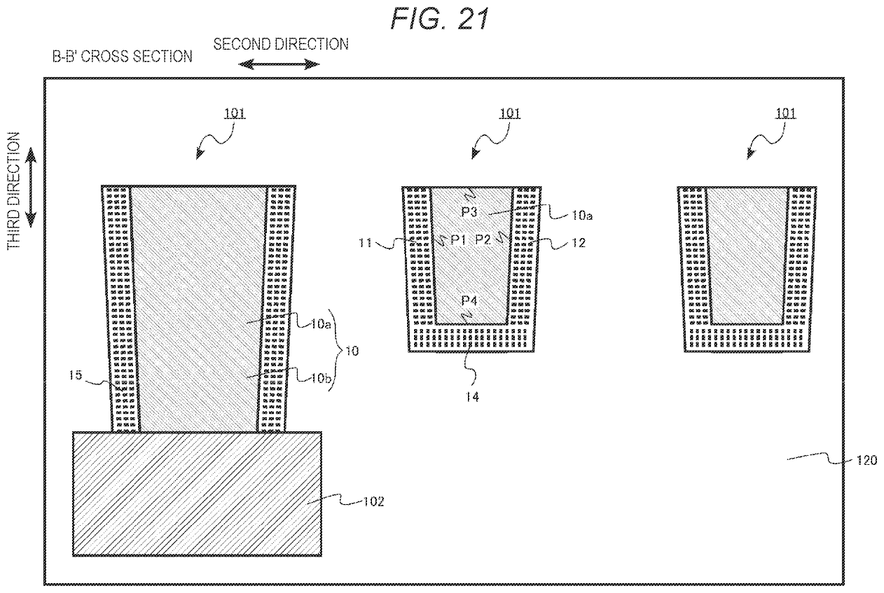

FIG. 21 is a schematic cross-sectional view of a wiring layer of a modification of the semiconductor device according to the second embodiment. FIG. 21 is a diagram corresponding to FIG. 11.

The first wiring 101 of the modification is different from the first wiring 101 according to the second embodiment in that the first wiring 101 of the modification further includes a fourth region 14, and the fourth region is disposed on a fourth surface P4 side of the first conductive layer 10, contains the second element and the third element, and includes a fourth crystal.

The fourth region 14 is disposed on the fourth surface P4 side of the first portion 10a of the first conductive layer 10. The fourth region 14 is in contact with, for example, the first portion 10a. The fourth region 14 is in contact with, for example, the fourth surface P4 of the first portion 10a.

The fourth region 14 contains the second element which is at least one element selected from the group consisting of tungsten (W) or molybdenum (Mo), and the third element which is at least one element selected from the group consisting of sulfur (S), selenium (Se), or tellurium (Te). The first element and the second element may be the same element or different elements. Hereinafter, the case where the third element is sulfur (S) will be described as an example.

Main components of the fourth region 14 contain the second element and sulfur (S). That is, among elements contained in the fourth region 14 other than the second element and sulfur (S), there is no element having an atomic concentration higher than the atomic concentration of the second element. In addition, among the elements contained in the fourth region 14 other than the second element and sulfur (S), there is no element having an atomic concentration higher than the atomic concentration of sulfur (S).

The fourth region 14 contains, for example, the sulfide of the second element. When the second element is tungsten (W), the fourth region 14 contains, for example, tungsten sulfide. When the second element is tungsten (W), the fourth region 14 contains, for example, tungsten disulfide (WS₂). The fourth region 14 contains, for example, WS₃, WO₂, or WO₃ as an impurity.

When the second element is molybdenum (Mo), the fourth region 14 contains, for example, molybdenum sulfide. When the second element is molybdenum (Mo), the fourth region 14 contains, for example, molybdenum disulfide (MoS₂). The fourth region 14 contains, for example, Mo₂S₃, MoO₂, or MoO₃ as an impurity.

The fourth region 14 is crystalline. The fourth region 14 contains the fourth crystal. The fourth crystal contains the second element and sulfur (S). The fourth crystal is a sulfide of the second element.

When the second element is, for example, tungsten (W), the fourth crystal contains tungsten (W) and sulfur (S). The fourth crystal is, for example, tungsten sulfide. The fourth crystal is, for example, tungsten disulfide.

When the second element is, for example, molybdenum (Mo), the fourth crystal contains molybdenum (Mo) and sulfur (S). The fourth crystal is, for example, molybdenum sulfide. The fourth crystal is, for example, molybdenum disulfide.

The fourth crystal has, for example, a layered structure in which the unit layers are stacked in the second direction. The fourth crystal has, for example, a layered structure in which the unit layers extending in a direction parallel to the fourth surface P4 are stacked in a direction perpendicular to the fourth surface P4.

When the fourth crystal is, for example, tungsten disulfide, each of the unit layers contains tungsten and sulfur. When the fourth crystal is, for example, molybdenum disulfide, the unit layer contains molybdenum and sulfur.

The fourth crystal is, for example, a hexagonal crystal. An average direction of the fourth crystal in the c-axis direction is oriented in a direction perpendicular to an approximate plane of the fourth surface P4. The average direction of the fourth crystal in the c-axis direction has an inclination of 10 degrees or less with respect to the direction perpendicular to the approximate plane of the fourth surface P4.

The fourth crystal is a two-dimensional crystal. The fourth crystal includes, for example, a plurality of unit layers of one layer or more and ten layers or less. In addition, the fourth crystal includes, for example, a plurality of unit layers of two layers or more and ten layers or less.

The unit layers of the two-dimensional crystal extend, for example, in the direction parallel to the fourth surface P4. The two-dimensional crystal has, for example, a layered structure in which the plurality of unit layers are stacked in the third direction.

Since the first wiring 101 of the modification includes the fourth region 14, it is possible to prevent the scattering of the free electrons on the lower surface of the first portion 10a of the first conductive layer 10. Therefore, a wiring having a lower electrical resistance can be achieved even if the wiring width is reduced. Accordingly, the wiring having a low electrical resistance can be achieved even if a thickness of the wiring is reduced.

Although the case where the third element is sulfur (S) is described above as an example, the third element may be selenium (Se) or tellurium (Te).

Although the side surfaces of the first wiring 101 form a reverse tapered shape in FIGS. 11 and 21, the side surfaces of the first wiring 101 may form, for example, a vertical shape or a forward tapered shape.

As described above, according to the second embodiment, it is possible to provide a semiconductor device provided with a wiring that prevents the scattering of the free electrons on a surface of the wiring and has a low electrical resistance even if the wiring width is reduced. Further, according to the second embodiment, it is possible to provide a semiconductor device provided with a wiring having a low wiring resistance on the contact plug portion.

### Third Embodiment

A semiconductor device according to a third embodiment is a three-dimensional NAND flash memory. In the semiconductor device according to the third embodiment, the first wiring according to the first embodiment is applied to each bit line of the three-dimensional NAND flash memory. Hereinafter, a part of a description of contents overlapping with that of the first embodiment will be omitted.

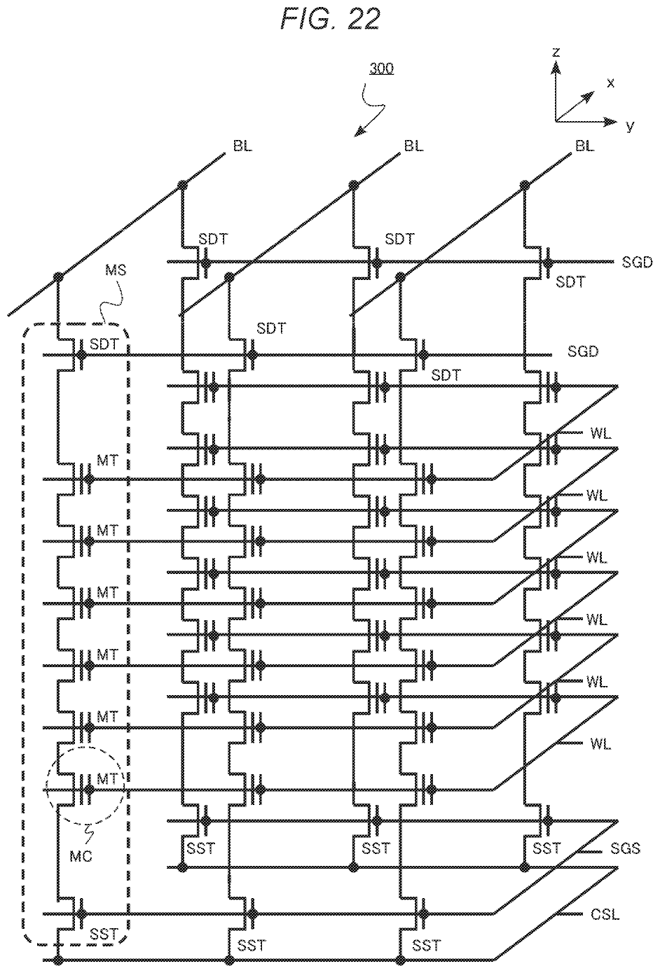

FIG. 22 is a circuit diagram of the semiconductor device according to the third embodiment. FIG. 22 is a circuit diagram of a memory cell array 300 of the three-dimensional NAND flash memory according to the third embodiment.

The memory cell array 300 of the three-dimensional NAND flash memory according to the third embodiment includes a plurality of word lines WLs, a common source line CSL, a source select gate line SGS, a plurality of drain select gate lines SGDs, a plurality of bit lines BLs, and a plurality of memory strings MSs, as shown in FIG. 22.

The plurality of word lines WLs are arranged apart from each other in a z direction. The plurality of word lines WLs are stacked and arranged in the z direction. The plurality of memory strings MSs extend in the z direction. The plurality of bit lines BLs extend, for example, in an x direction. The plurality of bit lines BLs extend, for example, at a predetermined pitch in a y direction.

As shown in FIG. 22, each of the memory strings MSs includes a source select transistor SST, a plurality of memory cell transistors MTs, and a drain select transistor SDT that are connected in series between the common source line CSL and each of the bit lines BLs. One memory string MS can be selected by selecting one bit line BL and one drain select gate line SGD, and one memory cell MC can be selected by selecting one word line WL. The word line WL functions as a gate electrode of the memory cell transistor MT that forms the memory cell MC.

In order to highly integrate the three-dimensional NAND flash memory, it is necessary to miniaturize the memory cell MC. In association with the miniaturization of the memory cell MC, a distance between adjacent memory strings MSs is also reduced. Therefore, the pitch at which the bit lines BLs are arranged is also reduced. Accordingly, it is necessary to reduce a width of the bit line BL.

When the width of the bit line BL is reduced, an electrical resistance of the bit line BL increases. When the electrical resistance of the bit line BL increases, for example, a time for writing data to the memory cell MC using the bit line BL as a signal line may increase, and for example, a time for reading data from the memory cell MC using the bit line BL as the signal line may increase.

If the time for writing data to the memory cell MC increases or the time for reading data from the memory cell MC increases, speeding up of the three-dimensional NAND flash memory is hindered.

In the three-dimensional NAND flash memory according to the third embodiment, the first wiring 101 according to the first embodiment is applied to the bit line BL. Therefore, a three-dimensional NAND flash memory provided with bit lines BLs having a low electrical resistance can be achieved even if the width of the bit line BL is reduced. Accordingly, the speeding up of the three-dimensional NAND flash memory can be achieved.

The first wiring 101 according to the second embodiment can also be applied to the bit line BL in place of the first wiring 101 according to the first embodiment.

As described above, according to the third embodiment, it is possible to provide a semiconductor device provided with a wiring that prevents scattering of free electrons on a surface of the wiring and has a low electrical resistance even if a wiring width is reduced.

In the third embodiment, the three-dimensional NAND flash memory is described as an example of the semiconductor device, but the semiconductor device of the present disclosure is not limited to the three-dimensional NAND flash memory. For example, the semiconductor device of the present disclosure may be a semiconductor memory other than the three-dimensional NAND flash memory. The semiconductor device of the present disclosure may be, for example, a logic device. The semiconductor device of the present disclosure may be, for example, a CMOS sensor.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first conductive layer extending in a first direction, the first conductive layer including a first surface, a second surface facing the first surface in a second direction intersecting the first direction, a third surface, and a fourth surface facing the third surface in a third direction, the third direction intersecting the first direction and the second direction, the first conductive layer containing a first element which is at least one element selected from a group consisting of tungsten (W) or molybdenum (Mo);
a first region disposed on a first surface side of the first conductive layer, the first region containing a second element and a third element, is the second element being at least one element selected from the group consisting of tungsten (W) or molybdenum (Mo), the third element being at least one element selected from a group consisting of sulfur (S), selenium (Se), or tellurium (Te), and including a first crystal; and
a second region disposed on a second surface side of the first conductive layer, the second region containing the second element and the third element, and including a second crystal.

2. The semiconductor device according to claim 1, wherein the first crystal has a layered structure in which a plurality of unit layers are stacked in the second direction, and the second crystal has a layered structure in which a plurality of unit layers are stacked in the second direction.

3. The semiconductor device according to claim 1, wherein the first crystal is a hexagonal crystal, and the second crystal is a hexagonal crystal.

4. The semiconductor device according to claim 1, wherein the first crystal is a two-dimensional crystal, and the second crystal is a two-dimensional crystal.

5. The semiconductor device according to claim 4, wherein the first crystal includes a plurality of unit layers, the plurality of unit layers of the first crystal having two layers or more and ten layers or less, and the second crystal includes a plurality of unit layers, the plurality of unit layers of the second crystal having two layers or more and ten layers or less.

6. The semiconductor device according to claim 1, wherein a length of the first conductive layer in the second direction is shorter than a length of the first conductive layer in the third direction.

7. The semiconductor device according to claim 1, wherein a length of the first region in the second direction is shorter than a length of the first conductive layer in the second direction, and a length of the second region in the second direction is shorter than the length of the first conductive layer in the second direction.

8. The semiconductor device according to claim 1, wherein the first element and the second element are the same element.

9. The semiconductor device according to claim 1, further comprising:
a third region disposed on a third surface side of the first conductive layer, the third region containing the second element and the third element, and the third region including a third crystal.

10. The semiconductor device according to claim 1, further comprising:
a conductive film disposed on a fourth surface side of the first conductive layer, wherein
a length of the conductive film in the second direction is longer than a length of the first conductive layer in the second direction.

11. The semiconductor device according to claim 1, further comprising:
an insulating film disposed on a third surface side of the first conductive layer and the insulating film being in contact with the third surface.

12. The semiconductor device according to claim 1, further comprising:
a fourth region disposed on a fourth surface side of the first conductive layer, the fourth region containing the second element and the third element, and the fourth region including a fourth crystal.

13. The semiconductor device according to claim 1, further comprising:
a second conductive layer electrically connected to the first conductive layer; and
a third conductive layer electrically connected to the first conductive layer.

14. The semiconductor device according to claim 1, further comprising:
a second conductive layer electrically connected to the first conductive layer; and
a fifth region containing the second element and the third element, and the fifth region including a fifth crystal, wherein
the first conductive layer includes:
a first portion extending in the first direction, and
a second portion disposed between the first portion and the second conductive layer, and being in contact with the second conductive layer, and
the fifth region surrounding the second portion.

15. A method for manufacturing a semiconductor device, comprising:
forming a conductive layer containing at least one metal element selected from a group consisting of tungsten (W) or molybdenum (Mo);
patterning the conductive layer; and
performing a first heat treatment to sulfurize a surface of the patterned conductive layer.

16. The method for manufacturing a semiconductor device according to claim 15, wherein the first heat treatment is performed at a temperature of 300° C. or higher and 900° C. or lower.

17. The method for manufacturing a semiconductor device according to claim 15, further comprising:
performing a second heat treatment, after the first heat treatment, the second heat treatment being performed at a temperature higher than a temperature of the first heat treatment.

18. The method for manufacturing a semiconductor device according to claim 17, wherein the second heat treatment is performed in a non-oxidizing atmosphere.

19. The method for manufacturing a semiconductor device according to claim 15, wherein the first heat treatment is performed in an atmosphere containing plasma of hydrogen sulfide.

20. The method for manufacturing a semiconductor device according to claim 15, wherein the first heat treatment is performed at a temperature of 300° C. or higher and 800° C. or lower in an atmosphere containing plasma of hydrogen sulfide, and is performed at a temperature of 500° C. or higher and 900° C. or lower in an atmosphere containing a hydrogen sulfide gas and containing no plasma of hydrogen sulfide.
